(19) United States
(12) Patent Application Publication
(10) Pub. No.: US 2026/0353528 A1
(43) Pub. Date: Nov. 5, 2026

(54) SYSTEMS, DEVICES, AND METHODS FOR LED MODULATION

(71) Applicant: ams-OSRAM AG, Premstaetten (AT)

(72) Inventor: Tim BOESCKE, Regensburg (DE)

(21) Appl. No.: 19/488,650

(22) PCT Filed: Sep. 24, 2024
(86) PCT No.: PCT/EP2024/076759

§ 371 Date: Nov. 28, 2025

(30) Foreign Application Priority Data
Sep. 27, 2023 (DE) 10 2023 126 331.5

(51) Int. Cl. H05B 45/10

(52) U.S. Cl. CPC H05B 45/10

(57) ABSTRACT

A circuit arrangement for driving light-emitting diodes includes a first modulator configured to modulate an input based on a first part of an intensity input value, and a second modulator configured to modulate an input including a sum of a second part of the intensity input value and an output of the first modulator to output an intensity bitstream. The second part of the intensity input value is different from the first part of the intensity input value.

### CROSS-REFERENCE TO RELATED APPLICATIONS

This application is a 371 U.S. National Phase of PCT International Patent Application No. PCT/EP2024/076759 filed on Sep. 24, 2024, which claims priority from German Patent Application No. 102023126331.5 dated Sep. 27, 2023, the disclosures of which are incorporated by reference herein in their entirety for all purposes.

### FIELD

This present disclosure generally relates to circuits that drive light emitting diodes (LEDs).

### BACKGROUND

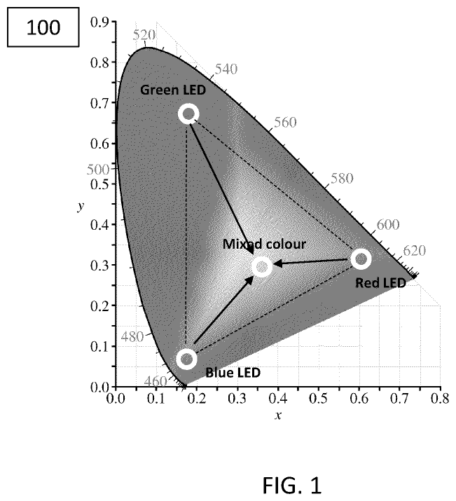

A red, blue, and green (RGB) LED allows rendering of most visible colors perceived by the human eye by changing the relative intensity of the emitters. FIG. 1 shows a graph 100 of red, green, and blue LED superimposed on a color space to show how a mixed color is achieved. One challenge is that color is defined by relative intensity of the emitters, hence the allowable relative error is small. A second challenge is that three orders of magnitude in luminance (brightness) is needed, and hence the resulting dynamic range is high. The following equations are for the intensity setting for RGB LEDS:

Intensity_{Red LED}=Luminance*R (1)

Intensity_{Green LED}=Luminance*G (2)

Intensity_{Blue LED}=Luminance*B (3)

Using the above equations, the intensity setting for each LED can be 17 bits. Luminance can be defined brightness, and be approximately 10 bits and have required absolute error 5% (common mode). The colors R, G, B, can be defined by approximately 7 bits with a max relative error of +−1%.

In general, changing the intensity of a LED by changing the driving current can be highly problematic. This is because:
The wavelength (color) changes with driving current
The dependence of luminance on driving current is highly nonlinear
Low current behavior degrades over time and has strong production variation/

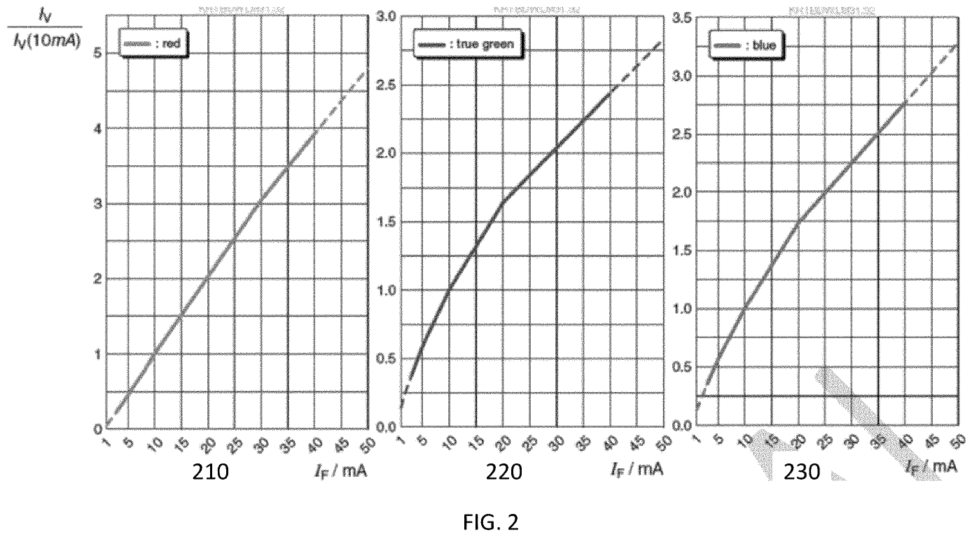

For example, FIG. 2 respectively shows graphs 210, 220, and 230 which are normalized luminous intensities for red, green, and blue emitters at different current with a temperature of 25 degrees Celsius and normalized to 10 mA. As shown in each graph, the intensity of the LEDs is nonlinear.

### DESCRIPTION

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1 shows a graph of a color space with red, green, and blue LEDs superimposed thereon to illustrate color mixing;

FIG. 2 shows graphs of normalized luminous intensities for red, green, and blue emitters at different current with a temperature of 25 degrees Celsius and normalized to 10 mA;

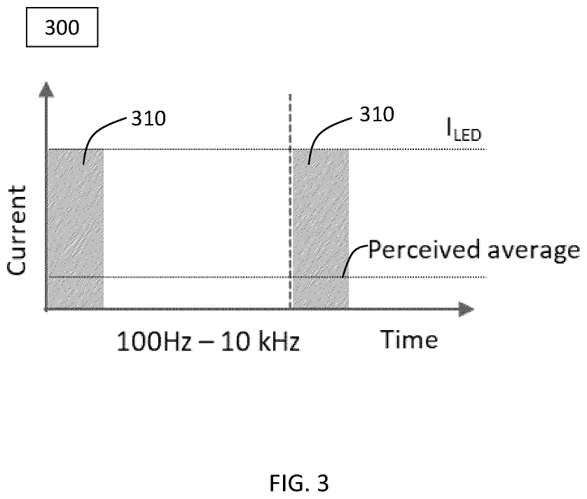

FIG. 3 shows a graph of pulses modulated according to pulse width modulation (PWM) scheme at a constant current;

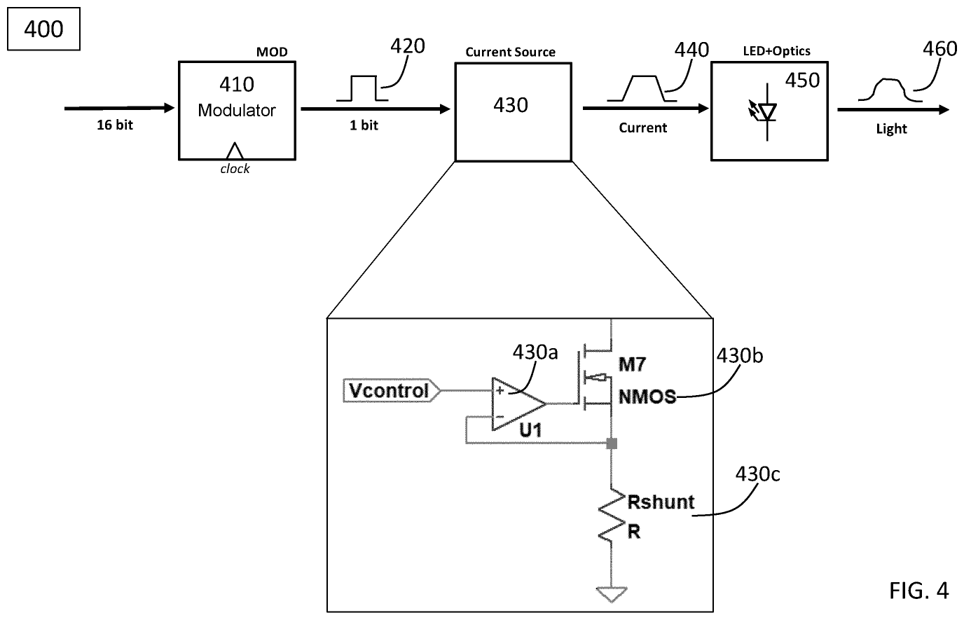

FIG. 4 shows a block diagram of an led driver chain arrangement according to one or more embodiments of the present disclosure;

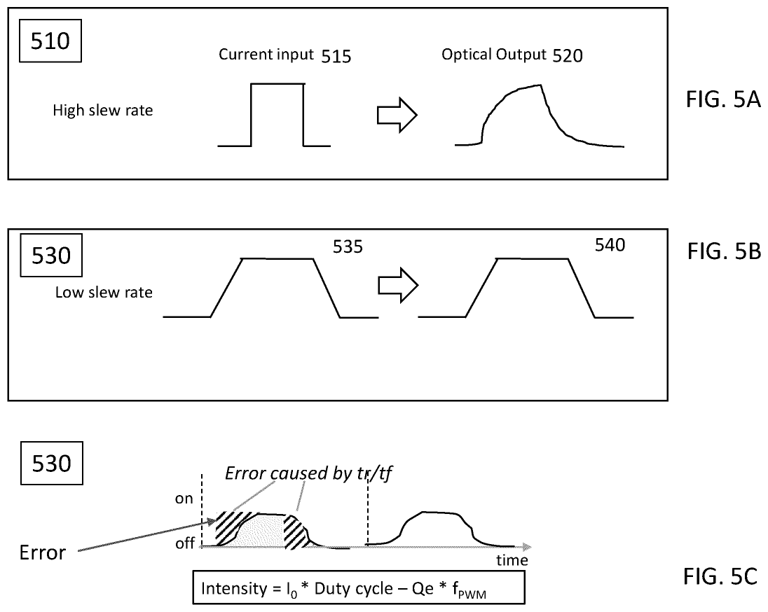

FIG. 5A to FIG. 5C includes graphs of LED current inputs and optical outputs and errors produced in the optical outputs;

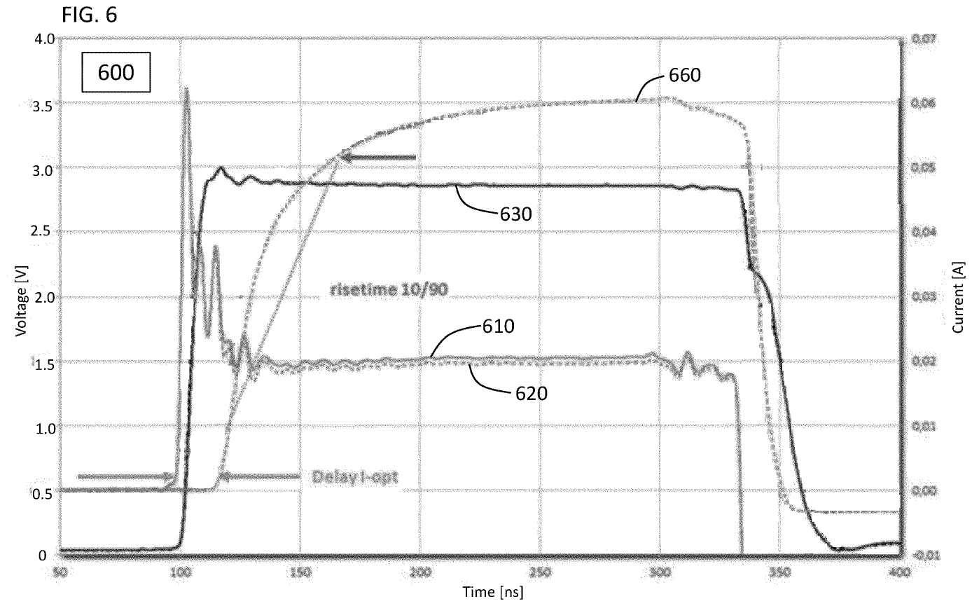

FIG. 6 includes graphs of transient response of optical output to LED currents;

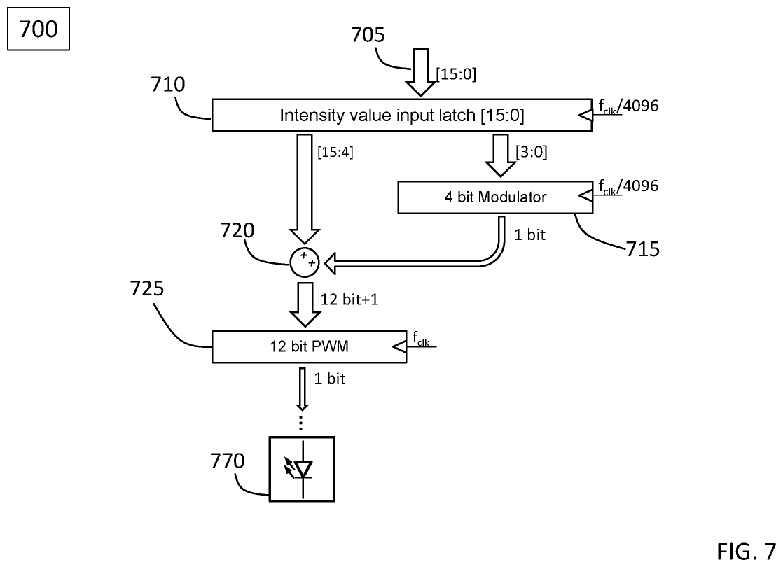

FIG. 7 illustrates a modulator circuitry component according to an aspect of the present disclosure; and

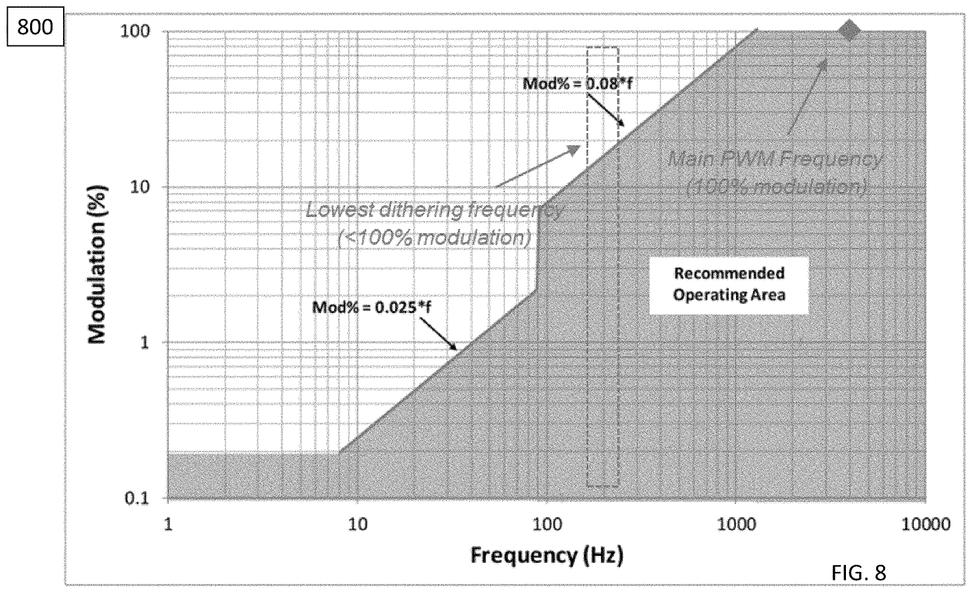

FIG. 8 shows a graph showing operating areas of a modulator circuitry of FIG. 7;

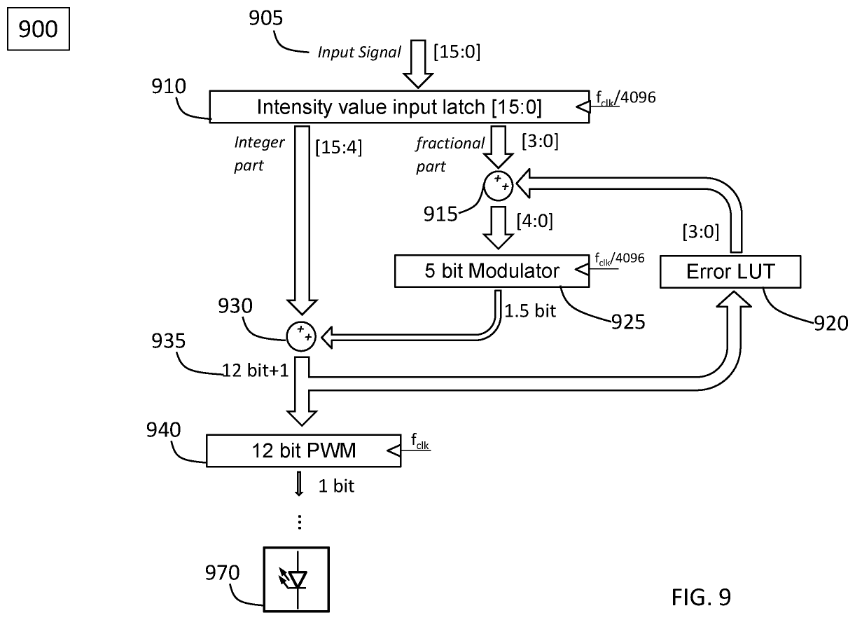

FIG. 9 illustrates a modulator circuitry component according to an aspect of the present disclosure;

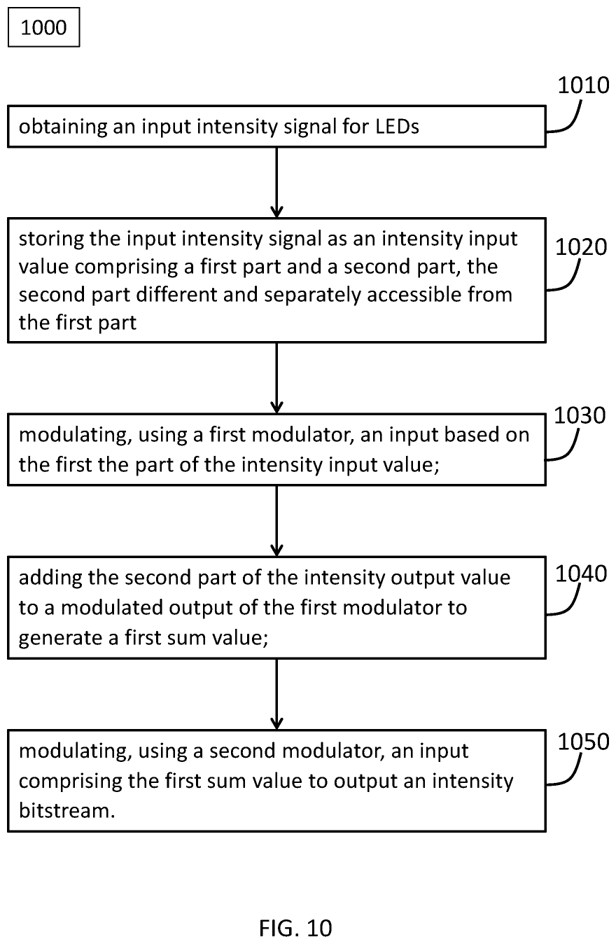

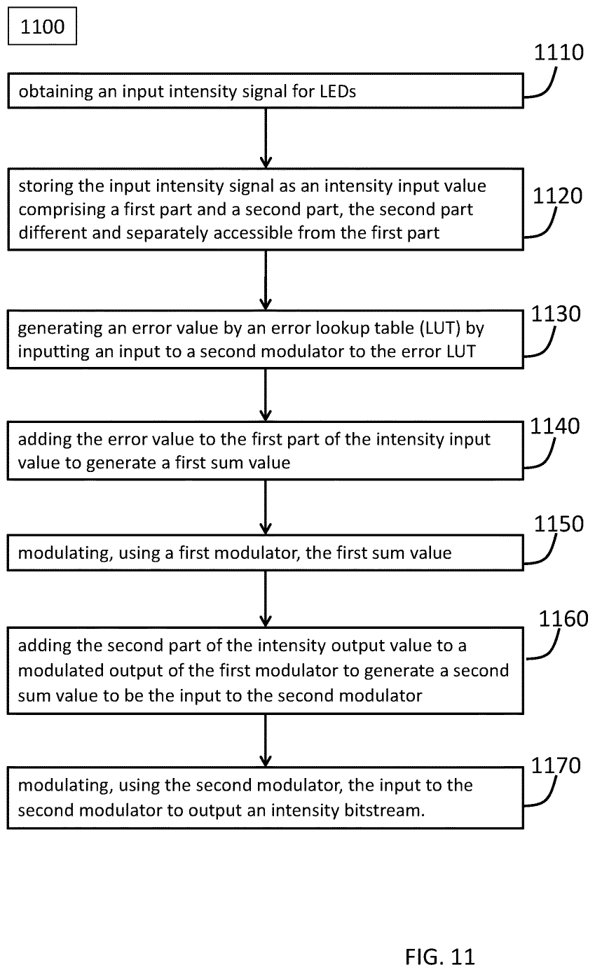

FIG. 10 to FIG. 11 are flow diagrams of method for modulating an intensity signal for driving LEDs;

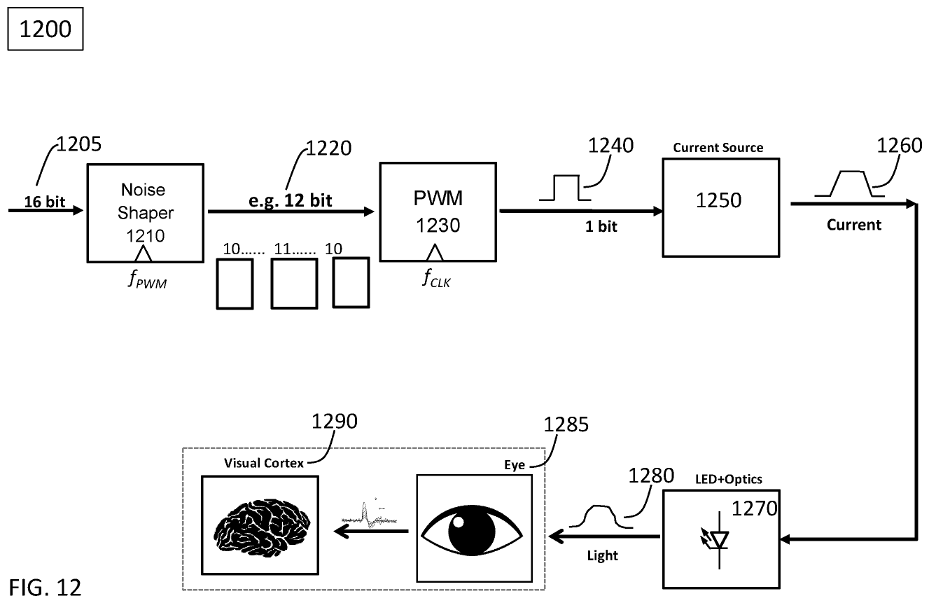

FIG. 12 illustrates driver signal chain arrangements according to aspects of the present disclosure.

The following detailed description refers to the accompanying drawings that show, by way of illustration, specific details and aspects in which the disclosure may be practiced. One or more aspects are described in sufficient detail to enable those skilled in the art to practice the disclosure. Other aspects may be utilized and structural, logical, and electrical changes may be made without departing from the scope of the disclosure. The various aspects described herein are not necessarily mutually exclusive, as some aspects can be combined with one or more other aspects to form new aspects. Various aspects are described in connection with methods and various aspects are described in connection with devices. However, it may be understood that aspects described in connection with methods may similarly apply to the devices, and vice versa. Throughout the drawings, it should be noted that like reference numbers are used to depict the same or similar elements, features, and structures. Throughout the drawings, it should be noted that proportions are not necessary to scale and that the size of features may be emphasized for ease of illustration.

Current solutions may include driving an LED at a fixed current, using pulse width modulation to control intensity. That is, in applications where the brightness of an LED needs to be controlled, it is commonplace to utilize pulse-width modulation where the LED is periodically turned off and on at a fixed driving current. The eye sees an averaged brightness that is proportional to the duty cycle. For example, FIG. 3 shows a graph 300 of pulses 310 modulated according to pulse width modulation (PWM) scheme at a constant current ILED and the corresponding perceived average current overlaid which controls the perceived brightness.

Benefits of this approach over current-based dimming
Realization as digital circuit is rather simple, circumvents the difficulty of building precision controllable variable current sources.
Most LEDS exhibit a nonlinear current/light output relationship. Pulse width modulation is inherently (almost) linear.

FIG. 4 shows a block diagram of an led driver chain arrangement 400 according to one or more embodiments of the present disclosure. The arrangement 400 includes a modulator 410 that may be circuitry configured to receive an intensity signal as an input and outputs an intensity bitstream signal 420.

The modulator 410 may be a pulse-width modulator that produces or outputs a pulse-width modulated bitstream signal at a fixed clock. This bitstream includes bits that act as on/off signals.

The bitstream signal 420 from the modulator 410 can be inputted or sent to a current source 430. The current source 430 produces load or LED currents 440, based on the bitstream signal 420, for the light-emitting diode (LED) module 450. That is, the current source 430 can produce currents that turn on and off the LEDS of LED module 450 according to the time resolved bitstream signal 420. FIG. 4 shows one example of a current source 430 which includes an opamp 430a in a negative feedback configuration, a NMOS transistor 430b and a shunt resistor 430c.

The LED module 450 includes optical circuitry and LEDs that produce light 460 based on the LED currents 440. The light outputted by the LED module can be transmitted to an eye and interpreted by visual cortex of a brain.

Accordingly, in the context of LED arrangements, such as the one shown in FIG. 4, LED brightness is controlled by turning LEDs quickly on and off and effective brightness is defined by duty cycle. However, a problem with such an arrangement is that LEDs do not instantly turn on and off.

FIG. 5 includes graphs 510 and 530 which show current inputs 515, 535 and optical outputs 520, 450 respectively for a high slew rate and a slow slew rate current inputs. FIG. 5 further includes a plot 550 indicating a systemic error caused by a limited slew rate. The intensity can be calculated a:

Intensity=I₀*Duty cycle−Qe*f_{PWM} (4)
wherein I₀ is drive current of LED fixed during PWM operation

In addition, second order like transient self-heating will create an additional, highly nonlinear error. It is suggested to perform compensation in software.

However, the charge error introduced by a non-ideal led response leads to a nonlinear error in brightness when employing pulse-width modulation or even more advanced modulations scheme.

FIG. 6 shows exemplary plots of input current currents to LED responses over time. The current 610/620 produces lagging responses 630 and 660, wherein 630 represents outputted on/off signal and 660 represents resulting light intensity over time.

An approach to solving the above mentioned issues would be to measure the averaged light output and using this as a feedback term to correct for this error. However, this type of approach is not possible in most applications as introducing measuring devices to reliability measure the light output is complex, costly and space consuming.

Therefore, an example of a solution that may be implemented for addressing the above described problem can be based on following assumptions or preconditions:
1) The introduced error by the rising and falling edges is constant when the LED is turned on for times much longer than the rise and fall time.
2) The introduced error is dependent on turn-on time if the turn-on time is short and close to the rise/fall time of the LED.

The above two preconditions can allow for a very efficient creation of a table with error terms. The table can be populated based on characterization of a golden device. Slew rate control of the current source allows it to be reproducible.

FIG. 7 shows an example of a modulator circuitry 700 that may be used in driving LEDs to avoid one or more of the issues described above. For example, while pulse-width modulation generally remains as the only realistic option to minimize charge error, scaling to higher number of bits using pulse-width modulation may not be possible because the number of cycles doubles with every additional input. For example, with a 12 MHz pulse-width modulation clock and a 16-bit input, a pulse width modulation frame would be 183 Hz, which would lead to unacceptable error.

The modulator circuitry 700 may be used, for example, in the context of FIG. 4, in place of the modulator 410. As shown, the modulator circuitry 700 includes an input latch circuit 710 that is configured to store input. For one or more clock cycles (fclk/4096), the latch circuit 710 can store an intensity input value. The intensity input value can be a value that indicates or sets a color and intensity to be produced by LEDs.

For example, for one or more clock cycles, the latch circuit 710 can receive an intensity input signal, e.g., analog or digital, which the latch circuit 710 stores as an intensity input value. Further, the latch circuit 710 can provide the stored intensity input value to other components. In at least one example, the latch circuit 710 can provide the stored intensity input value in parts. For example, a first part of the intensity input value may be provided to a first component while a second part of the intensity input value may be provided to a second, different component. That is, the latch circuit 710 may provide parts of the intensity input value separately, and in parallel to different components.

In the example of FIG. 7, the latch circuit 710 can be configured to separately provide a first part and a second part of intensity input value stored in the latch circuit 710.

For instance, the first part of the intensity input value may be an integer part or high frequency part for pulse-modulated width signal. The integer part or high frequency first part may be certain or a predefined selection of the most-significant bits of the intensity input value.

Similarly, the second part may be the fractional part or the lower frequency part. This second part can correspond to certain least-significant bits of the intensity input value. In the case of FIG. 7, wherein the intensity input value is 16-bits, the first part may be the most significant 12 bits, e.g., bit 4 to bit 15 and the second part can be the least significant 4 bits, bit 0 to bit 3. While stored intensity input value is described as 16 bits in size, other sizes may be realized or implemented.

As shown, in FIG. 7, the second part or fractional part of the intensity input value is provided to a modulator 715. In this instance, the modulator is a 4-bit modulator which modulates the input value to produce a 1-bit result. (In other cases, where appropriate the modulator may take other sizes of the second part of intensity input value). The first modulator 715 can be considered as an error modulator.

The first modulator 715 can be implemented as any suitable modulator including a sigma delta modulator, a pulse width modulator, a pseudo random binary sequence (PRBS) modulator, or a pulse-width modulator operated at a lower frequency. The sigma-delta modulator may be beneficial because it can optimize frequency usage. Further, a special property of sigma delta modulator is that it always maximizes that modulation frequency in respect to the desired averaged output sequence (e.g., 50% is encoded as 0101010101010101 instead of 0000000011111111 as a PWM modulator would encode).

The output of the modulator 715 may be considered as a dithering value and is added to the first part of the intensity input value. For example, an adder circuit 720 can add the output of the first modulator 715 with the first part of the intensity input value to produce a sum value. This sum value can be provided as an input to a second modulator 725. The second modulator 725 may be considered as a main modulator. Accordingly, the sum value can have a size less than the size of the intensity input value. In the example of FIG. 7, where the intensity input value is 16 bits, the first is 12 bits and the second part 4 bits, the sum value used as input to the second modulator 725 can be 12 bits.

The second modulator 725 can modulate the input, e.g., the sum value, to produce an output intensity bit stream that ultimately controls LEDS of a LED module 770. That is, the output intensity bitstream can be provided to a current source (not shown in FIG. 7), which generates LED currents based on the output intensity bitstream for the LED module.

The second modulator 725 can be a pulse-width modulator that generates, for one or more clock cycles, a pulse-width modulated signal based on the input.

In general, the modulator circuitry 700 can be configured to separate an intensity input value into a high frequency part with lower resolution (e.g., 16 bits to 12 bits) and a lower frequency part or fractional part (high resolution part) to be used for producing dithering signal that is modulated and then added to the high frequency part. That is, the example of FIG. 7 shows a 16-bit intensity input converted into a 12-bit pulse-width modulated signal with 4-bit dithering.

In one example case, a 12 MHz clock, can be used to produce 3 kHz pulse-width modulate signal in which the modulator clock is 12 MHZ/4096(~3 KHZ). In this case, the lowest modulator frequency may be 3 kHz/16 or ~183 Hz. For example, if the first or error modulator 715, has a 4 bit input and if the input is 1/16, then it is configured to output a sequence that is 1/16 time averaged. In this corner case, a one would only be output for every 16^{th} clock cycle, which is 3 kz/16=183 Hz.

FIG. 8 shows an example of graph 800 showing a relationship between modulation percentage and frequency and flicker visibility. The shaded gray part represents the operating area where flickering is not visible while the unshaded region is the operating area where flickering is visible.

FIG. 9 shows another example of a modulator circuitry 900 according to at least one example of the present disclosure. The modulator circuitry 900 can be used in driving LEDs. The modulator circuitry 900 can avoid one or more of the issues described above. For example, the modulator circuitry 900 can include circuitry that acts as an error accumulation register that sums up charge errors based on an internal feedback loop and a lookup table (LUT).

The modulator circuitry 900 includes an input latch circuit 910 that is configured to store an intensity input value. That is, for one or more clock cycles (fclk/4096), the latch circuit 910 can store an intensity input value. As described in FIG. 7, the intensity input value can be a value that indicates or sets a color and intensity to be produced by LEDS.

Specifically, the latch circuit 910 can be configured to receive an intensity input signal, e.g., analog or digital, and store the intensity input signal as an intensity input value. Similar to the latch circuit 710, the latch circuit 910 can provide the stored intensity input value to other components, e.g., in parts. For example, the latch circuit 910 can provide a first part of the intensity input value to a first component while a second part of the intensity input value may be provided to a second, different component. In other words, the latch circuit 910 may provide parts of the intensity input value separately, and in parallel to different components.

The first part of the intensity input value may be an integer part or high frequency part. The integer part or high frequency first part may be certain or a predefined selection of the most-significant bits of the intensity input value.

The second part may be a fractional part of the lower frequency part. This second part can correspond to certain or a predefined selection of the least-significant bits of the intensity input value.

In FIG. 9, the intensity input is 16-bits. In this case, the first part of the intensity input value is the twelve most significant bits, bit 4 to bit 15, and the second part is the four least significant 4 bits, bit 0 to bit 3. In other cases, the size of the intensity input value, as well as the size and locations of the first part and second part may vary.

As shown in FIG. 9, the second part or fractional part of circuit 915. Additionally, the output of an error lookup table (LUT), an error value, is also provided to the adder 915. The adder 915 sums the second part of the intensity input value and the error LUT output to generate a sum value.

As shown in FIG. 9, the sum value from the adder 915 is provided as input to the first modulator 925. The first modulator 925 can modulate this sum value to generate an output, which can then be provided as an input to the adder or adder circuit 930.

The first modulator 925 can be implemented as any suitable modulator including a sigma delta modulator, a pulse width modulator, or a pseudo random binary sequence (PRBS) modulator.

Further, the integer part of the first part of the intensity input value can also be provided as an input to the adder 930. The adder 930 sums the first part of the intensity input value with the output of the modulator 925 to generate a second sum value which is used as input for the second modulator 940. Further, this second sum value is used as feedback. Specifically, the second sum value is used as input to the error LUT 920. Based on the second sum value, the error LUT 920 outputs an error value to be summed with the second or fractional part of the intensity input value.

The error LUT 920 can be a lookup table circuit populated with values based on characterization data. For example, the characterization data may be derived or based on light output measurements on a golden device which have been performed for certain corner cases, e. g. where the intensity setting is very low. For setting where the duty cycle of the main PWM engine is sufficiently long (e.g. longer than 3-4 clock cycle), the error will not change with PWM setting anymore and the table can be compressed utilizing this fact. In one example, a table could hold different values for PWM setting=1, 2, 3, 4 and for values above 4, the same value as for 4 is used). “PWM setting” refers to the output value of the first modulator, specifically the set value (e.g., 12 bit) that is fed into the PWM engine.

The second modulator 940 modulates the input/second sum value to output a bitstream signal for controlling LEDS, e. g., LEDs of a LED module 970. For example, the output intensity bitstream can be provided to a current source (not shown in FIG. 9), which generates LED currents based on the output intensity bitstream for the LED module.

The second modulator 940 can be a pulse-width modulator that generates, for one or more clock cycles, a pulse-width modulated signal from the input. For each clock cycle, the modulator can generate a 1-bit output stream.

As shown, the modulator circuitry 900 uses the error LUT 920 as part of a feedback loop. The use of the error values provided by the error LUT to correct using the modulated input, e.g., pulse-width modulated, input to

Further, the modulator 925, which is configured to modulate the sum of the fractional part of the intensity input value and the error value, operates or functions as an error accumulator that sums up the charge errors. In other words, the feedback loop allows the modulator to sum up values charges that are present in the LEDs, but would not usually be accounted for or represented in the output bitstream used to control the LEDs. By adding the values representing charge errors from the internal feedback loop, the modulator circuitry 930 can effectively linearize its output and compensate for non-linear effects exhibited by LEDS. For example, the modulator circuitry 900 may be able compensate for self-heating effects.

FIG. 10 is a flow diagram of method or process 1000 for modulating an intensity input signal according to one or more examples of the present disclosure. The process 1000 may be implemented by modulator circuitries described herein, such as the modulator circuitry 700. The process 1000 may include performing, for one or more clock cycles the following:

At 1010, the process 1000 includes obtaining an input intensity signal for LEDs and then at 1020, storing the input intensity signal as an intensity input value comprising a first part and a second part, the second part different and separately accessible from the first part. At 1030, the process 1000 includes modulating, using a first modulator, an input based on the first the part of the intensity input value, and at 1040, adding the second part of the intensity output value to a modulated output of the first modulator to generate a first sum value. At 1050, the process includes modulating, using a second modulator, an input comprising the first sum value to output an intensity bitstream.

FIG. 11 is a flow diagram of process 1100 for modulating an intensity input signal according to one or more examples of the present disclosure. The process 1100 may be implemented by modulator circuitries described herein, such as the modulator circuitry 900. The process 1100 may include performing, for one or more clock cycles the following:

At 1110, the process 1000 includes obtaining an input intensity signal for LEDs and then at 1120, storing the input intensity signal as an intensity input value comprising a first part and a second part, the second part different and separately accessible from the first part. At 1130, the process 1100 includes generating an error value by an error lookup table (LUT) by inputting an input to a second modulator to the error LUT, and then at 1140, the process 1100 includes adding the error value to the first part of the intensity input value to generate a first sum value. At 1150 the process 1100 includes modulating, using a first (error) modulator, the first sum value. At 1160, the process includes adding the second part of the intensity output value to a modulated output of the first modulator to generate a second sum value to be the input to the second modulator. At 1170, the process 1100 includes modulating, using the second (main) modulator, the input to the second modulator to output an intensity bitstream.

The processes 1000 and 1100 may include further steps for driving LEDS. For example, the outputted intensity bitstream signal from each process can be applied to a current source to generate LED or load currents which are applied to LEDs, e.g., of a LED module to generate light.

FIG. 12 shows a block diagram of another led driver chain or arrangement 1200 according to one or more embodiments of the present disclosure. The arrangement 1200 includes a noise shaper 1210 that be circuitry configured to modify an intensity signal so to provide a lower resolution input 1220 to the pulse modulator 1230.

The modulator 410 may be a pulse-width modulator that produces or outputs a pulse-width modulated bitstream signal at a fixed clock. This bitstream includes bits that act as on/off signals.

The bitstream signal 1230 from the modulator 410 can be inputted or sent to a current source 1250. The current source 12500 produces load or LED currents 1260, based on the bitstream signal 1260, for the light-emitting diode (LED) module 1270. That is, the current source 1250 can produce currents that turn on and off the LEDs of LED module 1270 according to the bitstream signal 1240.

The LED module 1270 includes optical circuitry and LEDs that produce light 1280 based on the LED currents 1260. The light outputted by the LED module which can be transmitted to an eye 1285 and interpreted by visual cortex of a brain 1290.

While FIG. 7 and FIG. 9 both describe modulator circuitries 700 and 900, aspects of modulator circuitries can be considered or serve as the noise shaper in an LED drive signal chain arrangement, such as the noise shaper 1210 in the example of FIG. 12. For example, the components 710 to 720, which produce an output or value to that serves as input to the modulator 725 (e.g., pulse-width modulator). These components can be considered as a “noise shaper”. In other words, such components appropriately modify and shape the intensity input value for use by the modulator 725.

Similarly, in FIG. 9, the components 910 to 935 can also be a noise shaper that also serves to beneficially modify the input intensity value for the modulator 940 (e.g., pulse width modulator).

### EXAMPLE SECTION—GENERAL CLAIM SET

In the following some examples are described, which relate to what is described herein and shown in the figures.

Example 1 is a circuit arrangement for driving light-emitting diodes including: a first modulator configured to modulate an input based on a first part of an intensity input value; and a second modulator configured to modulate an input comprising a sum of a second part of the intensity input value and an output of the first modulator to output an intensity bitstream, wherein the second part of the intensity input value is different from the first part of the intensity input value.

Example 2 is the subject matter of Example 1,

wherein the first part of the intensity input value may be a fractional part of the intensity input value and the second part of the intensity input value may be an integer part of the intensity input value.

Example 3 is the subject matter of Example 1 or 2, which may further include: an input latch configured to store an intensity input signal as the intensity input value, and configured to provide the stored intensity input value separately as the integer part and the fractional part.

Example 4 is the subject matter of any of Examples 1 to 3, which may further include:
a first adder configured to add the output of the first modulator to the second part of the intensity input value to generate a first sum value;
an error look-up-table, LUT, configured to obtain as input, the first sum value from the first adder and to output an error value based on the first sum value; and
a second adder configured to add the first part of the intensity input value to the error value output to generate a second sum value,
   wherein the input to the fist modulator is the second sum value.

Example 5 is the subject matter of any of Examples 1 to 4, wherein the first modulator may be a sigma delta modulator, a pulse-width modulator, or a pseudo random binary sequence modulator.

Example 6 is the subject matter of any of Examples 1 to 5, wherein the second modulator may be a pulse-width modulator configured to output a pulse-width modulated bitstream.

Example 7 is the subject matter of any of Examples 1 to 6, wherein a size of the input to the second modulator may be a smaller size than a size of the intensity input value.

Example 8 is the subject matter of any of Examples 1 to 7, which may further include: a current source configured to obtain the output of the second modulator as input and to provide one or more load currents for a light-emitting diode, LED, module.

Example 9 is the subject matter of Example 8, which may further include: the LED module, comprising one or more LEDS and configured to receive the one or more load currents from the current source.

Example 10 is the subject matter of Example 9, wherein the one or more LEDs may be red, green, blue (RGB) type LEDs.

Example 11 is a method including:
obtaining an input intensity signal for light-emitting diodes, LEDS,
storing the input intensity signal as an intensity input value comprising a first part and a second part, the second part different and separately accessible from the first part;
modulating, using a first modulator, an input based on the first the part of the intensity input value;
adding the second part of the intensity output value to a modulated output of the first modulator to generate a first sum value;
modulating, using a second modulator, an input comprising the first sum value to output an intensity bitstream.

Example 12 is the subject matter of Example 11,

wherein the first part may be a fractional part of the intensity input value and the second part may be an integer part of the intensity input value.

Example 13 is the subject matter of Example 11 or 12, which may further include:
generating an error value by providing the first sum value to an error lookup table (LUT);
adding the error value to the first part of the intensity input value to generate a second sum value; and
providing the second sum value as input to the first modulator.

Example 14 is the subject matter of any of Example 11 to 13, wherein the first modulator comprises a sigma delta modulator, a pulse-width modulator, or a pseudo random binary sequence modulator.

Example 15 is the subject matter of any of Example 11 to 14, wherein the second modulator may be a pulse-width modulator configured to output a pulse-width modulated intensity bitstream.

Example 16 is the subject matter of any of Example 11 to 15, wherein the input to the second modulator has a size less than a size of the intensity input value.

Example 17 is the subject matter of any of Example 11 to 16, which may further include:
generating, using a current source, one or more load currents for a light-emitting diode, LED, module using the outputted intensity bitstream from the second modulator as input.

Example 18 is the subject matter of Example 17,
generating light by the LED module, comprising one or more LEDs, using the one or more load currents from the

The word “exemplary” is used herein to mean “serving as an example, instance, or illustration.” Any example or design described herein as “exemplary” is not necessarily to be construed as preferred or advantageous over other examples or designs.

The words “plurality” and “multiple” in the description or the claims expressly refer to a quantity greater than one. The terms “group (of)”, “set [of]”, “collection (of)”, “series (of)”, “sequence (of) ”, “grouping (of)”, etc., and the like in the description or in the claims refer to a quantity equal to or greater than one, i.e. one or more. Any term expressed in plural form that does not expressly state “plurality” or “multiple” likewise refers to a quantity equal to or greater than one.

The term “connected” can be understood in the sense of a (e.g. mechanical, optical and/or electrical), e.g. direct or indirect, connection and/or interaction. For example, several elements can be connected together mechanically such that they are physically retained (e.g., a plug connected to a socket) and electrically such that they have an electrically conductive path (e.g., signal paths exist along a communicative chain).

As used herein, unless otherwise specified the use of the ordinal adjectives “first”, “second”, “third” etc., to describe a common object, merely indicate that different instances of like objects are being referred to, and are not intended to imply that the objects so described must be in a given sequence, either temporally, spatially, in ranking, or in any other manner.

As utilized herein, terms “module”, “component,” “system,” “circuit,” “element,” “slice,” “circuitry,” and the like are intended to refer to a set of one or more electronic components, a computer-related entity, hardware, software (e.g., in execution), and/or firmware. For example, circuitry or a similar term can be a processor, a process running on a processor, a controller, an object, an executable program, a storage device, and/or a computer with a processing device. By way of illustration, an application running on a server and the server can also be circuitry. One or more circuits can reside within the same circuitry, and circuitry can be localized on one computer and/or distributed between two or more computers. A set of elements or a set of other circuits can be described herein, in which the term “set” can be interpreted as “one or more.”

While the above descriptions and connected figures may depict optical device components as separate elements, skilled persons will appreciate the various possibilities to combine or integrate discrete optical functions into single element. Such may include combining two or more components from a single component. Conversely, skilled persons will recognize the possibility to separate a single element into two or more discrete elements, such as splitting a single component into two or more separate components.

It is appreciated that implementations of methods detailed herein are exemplary in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

While the disclosure has been particularly shown and described with reference to specific embodiments, it should be understood by those skilled in the art that various changes in form and detail may be made therein without departing from the spirit and scope of the disclosure as defined by the appended claims. The scope of the disclosure is thus indicated by the appended claims and all changes which come within the meaning and range of equivalency of the claims are therefore intended to be embraced.

### REFERENCE NUMERAL LIST

100 graph
210, 220, and 230 graphs
300 graph
400 LED driver chain arrangement
410 modulator
420 intensity bitstream signal
430 current source
430a operational amplifier
430b transistor
430 resistor
440 LED current
450 LED and optical circuitry module
460 light or optical output
510-530 graphs of optical output
600 transient response graph
610, 620, 630, 640, 650, 660 plots of transient responses of
currents and optical output
700 modulator circuitry
705 intensity input signal
710 latch circuit
715 modulator
720 adder circuit
725 modulator
770 LED module
800 graph of operating area for LEDS
900 modulator circuitry
905 intensity input signal
910 latch circuit
915 adder circuit
920 error lookup table circuit
925 modulator
930 adder circuit
935 modulator input
940 modulator
1000 method
1010, 1020, 1030, 1040, 1050—method steps
1100 method
1110, 1120, 1130, 1140, 1150, 1160, 1170—method steps
1200 LED driver chain arrangement
1205 intensity input signal
1210 noise shaper circuit
1220 modified intensity input signal
1230 pulse width modulator
1250 modulator output
1250 current source
1260 LED current
1270 LED and optical circuitry module
1280 light or optical output
1285 eye
1290 brain/visual cortex

1. A circuit arrangement for driving light-emitting diodes comprising:
a first modulator configured to modulate an input based on a first part of an intensity input value;
a second modulator configured to modulate an input comprising a sum of a second part of the intensity input value and an output of the first modulator to output an intensity bitstream;
a first adder configured to add the output of the first modulator to the second part of the intensity input value to generate a first sum value;
an error look-up-table, LUT, configured to obtain as input, the first sum value from the first adder and to output an error value based on the first sum value; and
a second adder configured to add the first part of the intensity input value to the error value output to generate a second sum value wherein the second part of the intensity input value is different from the first part of the intensity input value.

2. The circuit arrangement of claim 1,
wherein the first part of the intensity input value is a fractional part of the intensity input value and the second part of the intensity input value is an integer part of the intensity input value.

3. The circuit arrangement of claim 1, further comprising:
an input latch configured to store an intensity input signal as the intensity input value, and configured to provide the stored intensity input value separately as the integer part and the fractional part.

4. The circuit arrangement of claim 1,
wherein the input to the fist modulator is the second sum value.

5. The circuit arrangement of claim 1,
wherein the first modulator comprises a sigma delta modulator.

6. The circuit arrangement of claim 1,
wherein the first modulator comprises a pulse-width modulator.

7. The circuit arrangement of claim 1,
wherein the first modulator comprises a pseudo random binary sequence modulator.

8. The circuit arrangement of claim 1,
wherein the second modulator is a pulse-width modulator configured to output a pulse-width modulated bitstream.

9. The circuit arrangement of claim
wherein a size of the input to the second modulator is smaller size than a size of the intensity input value.

10. The circuit arrangement of claim 1, further comprising:
a current source configured to obtain the output of the second modulator as input and to provide one or more load currents for a light-emitting diode, LED, module.

11. The circuit arrangement of claim 10, further comprising:
the LED module, comprising one or more LEDs and configured to receive the one or more load currents from the current source.

12. The circuit arrangement of claim 11,
wherein the one or more LEDs are red, green, blue (RGB) type LEDs.

13. A method comprising:
obtaining an input intensity signal for light-emitting diodes, LEDs, storing the input intensity signal as an intensity input value comprising a first part and a second part, the second part different and separately accessible from the first part;
modulating, using a first modulator, an input based on the first the part of the intensity input value;
adding the second part of the intensity output value to a modulated output of the first modulator to generate a first sum value;
modulating, using a second modulator, an input comprising the first sum value to produce a digital output of an intensity bitstream.

14. The method of claim 13,
wherein the first part is a fractional part of the intensity input value and the second part is an integer part of the intensity input value.

15. The method of claim 13, further comprising:
generating an error value by providing the first sum value to an error lookup table (LUT); adding the error value to the first part of the intensity input value to generate a second sum value; and
providing the second sum value as input to the first modulator.

16. The method of claim 13,
wherein the first modulator comprises a sigma delta modulator, a pulse-width modulator, or a pseudo random binary sequence modulator.

17. The method of claim 13,
wherein the second modulator is a pulse-width modulator configured to output a pulse-width modulated intensity bitstream.

18. The method of claim 13,
wherein the input to the second modulator has a size less than a size of the intensity input value.

19. The method of claim 13, further comprising:
generating, using a current source, one or more load currents for a light-emitting diode, LED, module using the outputted intensity bitstream from the second modulator as input.
